(19) United States
(12) Patent Application Publication
(10) Pub. No.: US 2021/0027342 A1
(43) Pub. Date: Jan. 28, 2021

(54) ADVERTISEMENT DISPLAY MANAGEMENT SYSTEM

(71) Applicant: TOYOTA JIDOSHA KABUSHIKI KAISHA, Toyota-sh (JP)

(72) Inventors: Hideshi MIZUTANI, Toyota-shi (JP); Ikuo OHTA, Toyota-shi (JP); Atsushi SAJIKI, Okazaki-shi (JP); Takao INATA, Tokyo-to (JP); Yohei TANIGAWA, Toyota-shi (JP); Atsushi NAKAJIMA, Kariya-city (JP); Atsuo KOMATSUBARA, Nagakute-shi (JP)

(73) Assignee: TOYOTA JIDOSHA KABUSHIKI KAISHA, Toyota-shi (JP)

(21) Appl. No.: 16/930,601

(22) Filed: Jul. 16, 2020

(30) Foreign Application Priority Data
Jul. 26, 2019 (JP) 2019-137819

(51) Int. Cl. G06Q 30/02; G01D 4/00; G01R 22/06

(52) U.S. Cl. CPC G06Q 30/0283; G01D 4/004; G06Q 30/0207; G06Q 30/0241; G01R 22/063

(57) ABSTRACT

An advertisement display management system includes: an acquisition unit configured to acquire, from a terminal device at a client company, an amount of electricity to be purchased for a prescribed period from the electricity generating facility where a renewable energy source is used and which is installed at an airport and data of an advertisement to be displayed at the airport during the prescribed period; a calculation unit configured to calculate an emission reduction amount of CO₂ equivalent to the amount of electricity to be purchased; and a display unit installed at the airport and configured to display the data of the advertisement, the amount of electricity to be purchased, and the emission reduction amount of CO₂.

### CROSS REFERENCE TO RELATED APPLICATIONS

This application is based upon and claims the benefit of priority from Japanese patent application No. 2019-137819, filed on Jul. 26, 2019, the disclosure of which is incorporated herein in its entirety by reference.

### BACKGROUND

The present disclosure relates to an advertisement display management system.

In recent years, companies have been requested to reduce emission amounts of greenhouse gases such as CO₂ in order to prevent global warming. Therefore, there is a trend among such companies to purchase electricity from electricity generating facilities where renewable energy sources such as solar power, wind power, geothermal power, hydraulic power, and biomass fuel are used. Japanese Unexamined Patent Application Publication No. 2013-242827 discloses a system in which a consumer who has installed a renewable energy generator consumes, for privates use, electricity generated using the renewable energy generator and sells off surplus electricity to an electricity supplier of consuming, for private use, electricity generated using a renewable energy generator installed by a consumer of the electricity and selling off surplus electricity to an electricity supplier or purchasing insufficient amount of electricity from the electricity supplier.

### SUMMARY

A study has been made on installing an electricity generating facility where a renewable energy is used at an airport and using the electricity generated by the electricity generating facility to cover all of the electricity consumed within the airport for the purpose of reducing emission of greenhouse gases, i.e., “zero-emissionziation”. Since the electricity generating facility where a renewable energy source is used varies in its capacity for generating electricity, consideration has been given on supplying companies who are making efforts to reduce the emission amount of greenhouse gases with the surplus electricity obtained by deducting the amount of electricity to be consumed at the airport from the total electricity generated at the electricity generating facility of the airport. However, in order to have the companies who are making efforts to reduce the emission amount of greenhouse gases purchase the electricity generated at the electricity generating facility of the airport, it has been necessary to give some sort of incentives to those companies.

The present disclosure has been made in view of the aforementioned background and its object is to provide an advertisement display management system by which it is possible to promote purchase of electricity generated at an electricity generating facility of an airport by a company who is making efforts to reduce the emission amount of greenhouse gases.

An advertisement display management system according to one exemplary aspect includes: an acquisition unit configured to acquire, from a terminal device at a client company, an amount of electricity to be purchased for a prescribed period from an electricity generating facility where a renewable energy source is used and which is installed at an airport and data of an advertisement that is to be displayed at the airport during the prescribed period; a calculation unit configured to calculate an emission reduction amount of CO₂ equivalent to the amount of electricity to be purchased; and a display unit installed at the airport and configured to display the data of the advertisement, the amount of electricity to be purchased, and the emission reduction amount of CO₂.

The advertisement display management system displays the advertisement of the client company who is planning to purchase electricity from the electricity generating facility installed at the airport, the amount of electricity to be purchased by the client company, and the emission reduction amount of CO₂ equivalent to the amount of electricity to be purchased on the display unit installed at the airport. By this structure, it is possible to promote purchase of electricity generated at the electricity generating facility of the airport by the client company who is making efforts to reduce the emission amount of greenhouse gases.

The advertisement display management system may further include a transmission unit configured to transmit information to the terminal device, in which: the calculation unit may be configured to calculate an amount of electricity that can be generated at the electricity generating facility during the prescribed period and the maximum amount of electricity that can be purchased by the client company based on information regarding the weather during the prescribed period; and the transmission unit may be configured to transmit information regarding the maximum amount of electricity that can be purchased by the client company to the terminal device before the acquisition unit acquires the amount of electricity to be purchased. By this structure, the client company can grasp, in advance, the amount of electricity that can be purchased from the electricity generating facility installed at the airport, and hence the client company can purchase the electricity generated using the renewable energy from the airport as planned.

Further, the calculation unit may be configured to calculate, in advance, a discount rate pertaining to a cost for displaying an advertisement at the airport in accordance with the amount of electricity to be purchased; and the transmission unit may be configured to transmit information regarding the discount rate to the terminal device before the acquisition unit acquires the amount of electricity to be purchased. By this structure, it is possible to promote purchase of electricity generated from the electricity generating facility of the airport where the renewable energy is used by the client company who has their advertisement displayed at the airport.

According to the present disclosure, it is possible to promote purchase of electricity generated at the electricity generating facility of the airport by a company who is making efforts to reduce the emission amount of greenhouse gases.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a block diagram showing a configuration of an advertisement display management system according to a first embodiment;

FIG. 2 is a flow chart showing flow of processes performed by the advertisement display management system according to the first embodiment;

FIG. 3 is a schematic diagram showing a detailed configuration of a display unit of the advertisement display management system according to the first embodiment;

FIG. 4 is a block diagram showing a configuration of an advertisement display management system according to a second embodiment;

FIG. 5 is a schematic diagram showing an example of information transmitted from a transmission unit of the advertisement display management system according to the second embodiment to a terminal device at a client company; and

FIG. 6 is a schematic diagram showing an example of information regarding the discount rate pertaining to the cost for displaying an advertisement at the airport that is transmitted from the transmission unit of the advertisement display management system according to the second embodiment to the terminal device at the client company.

### DESCRIPTION OF EMBODIMENTS

Hereinbelow, the present disclosure is explained through the embodiments, however the present disclosure according to the claims is not to be limited by the embodiments. Further, not all of the configurations described in the embodiments are essential for the means for solving the problem. For the sake of clarification, the description and the drawings mentioned below are omitted or simplified as appropriate. The same symbols are assigned to the same elements in the drawings and duplicated explanations are omitted as appropriate.

### First Embodiment

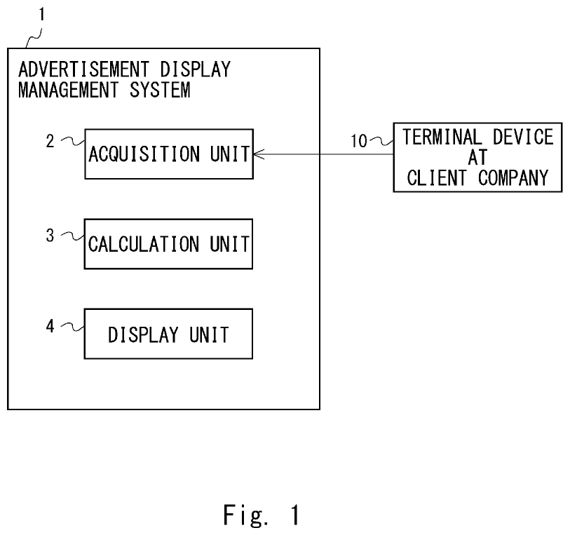

Firstly, a configuration of an advertisement display management system according to a first embodiment is explained with reference to FIG. 1. FIG. 1 is a block diagram showing the configuration of the advertisement display management system 1 according to the first embodiment. As shown in FIG. 1, an advertisement display management system 1 includes an acquisition unit 2, a calculation unit 3, and a display unit 4.

The acquisition unit 2 acquires, from a client terminal device 10 at a client company, an amount of electricity to be purchased for a prescribed period from the electricity generating facility where a renewable energy source is used and which is installed at the airport (hereinbelow referred to as an amount of electricity to be purchased) and data of an advertisement to be displayed at the airport during the prescribed period. Here, a renewable energy is an energy source that is repeatedly generated under the terrestrial environment and that can be recycled or supplied inexhaustibly such as solar power, wind power, biomass fuel, hydraulic power, geothermal power etc. The calculation unit 3 calculates an emission reduction amount of CO2 equivalent to the amount of electricity to be purchased. The display unit 4 is installed at the airport and displays the data of the advertisement, the amount of electricity to be purchased, and the emission reduction amount of CO₂.

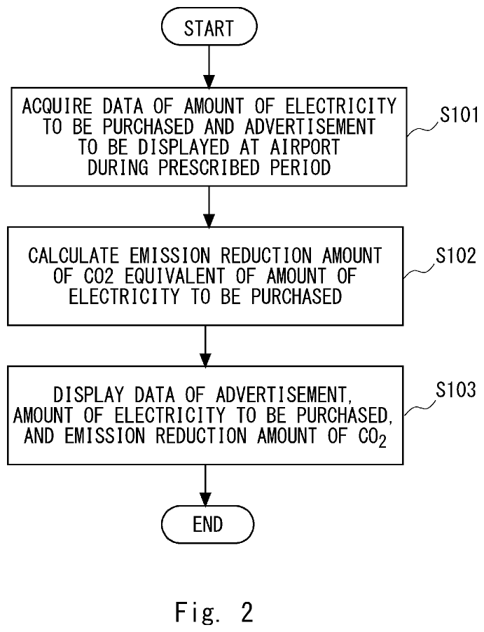

Next, flow of processes performed by the advertisement display management system 1 is explained below. Note that FIG. 1 is referred to as appropriate in the explanation given below. FIG. 2 is a flow chart showing flow of processes performed by the advertisement display management system 1. As shown in FIG. 2, first, the acquisition unit 2 acquires data of the amount of electricity to be purchased and the advertisement that is to be displayed at the airport during the prescribed period (Step S101). Next, the calculation unit 3 calculates the emission reduction amount of CO₂ equivalent to the amount of electricity to be purchased (Step S102). Next, the display unit 4 displays the data of the advertisement, the amount of electricity to be purchased, and the emission reduction amount of CO₂ (Step S103).

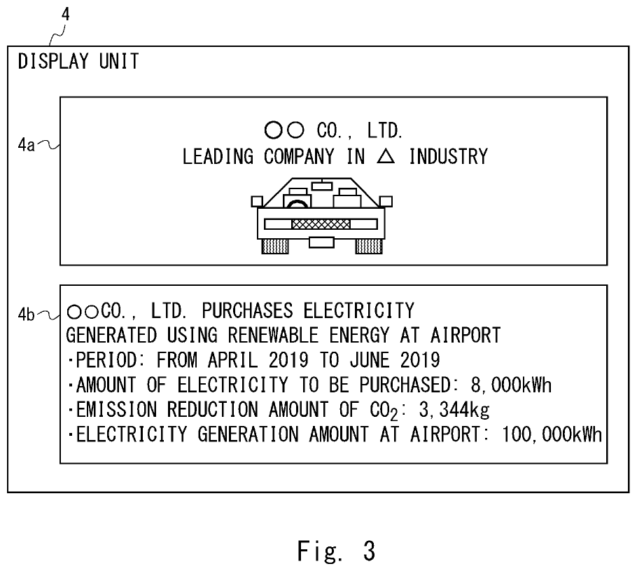

FIG. 3 is a schematic diagram showing a detailed configuration of the display unit 4. As shown in FIG. 3, the display unit 4 includes an advertisement display part 4a and a calculation result display part 4b. The advertisement display part 4a and the calculation result display part 4b are, for example, liquid crystal display screens. The advertisement display part 4a displays the data of the advertisement acquired by the acquisition unit 2 from the terminal device 10 at the client company. The calculation result display part 4b displays the amount of electricity to be purchased and the emission reduction amount of CO₂. For example, in a display example of the calculation result display part 4b shown in FIG. 3, the period for which the electricity generated using the renewable energy is purchased from the airport, the amount of electricity to be purchased, the emission reduction amount of CO₂ equivalent to the electricity to be purchased, and an electricity generation amount at the airport etc. are displayed. Regarding the data of the advertisement and the data of the calculation result, they are transmitted from the calculation unit 3 to the display unit 4 by cable transmission or wireless transmission.

As described above, the advertisement display management system 1 according to the first embodiment displays the advertisement of the client company who is planning to purchase electricity from the electricity generating facility installed at the airport, the amount of electricity to be purchased by the client company, and the emission reduction amount of CO₂ equivalent to the amount of electricity to be purchased on the display unit 4 installed at the airport. By this structure, it is possible to promote purchase of electricity generated at the electricity generating facility of the airport by the company who is making efforts to reduce the emission amount of greenhouse gases.

### Second Embodiment

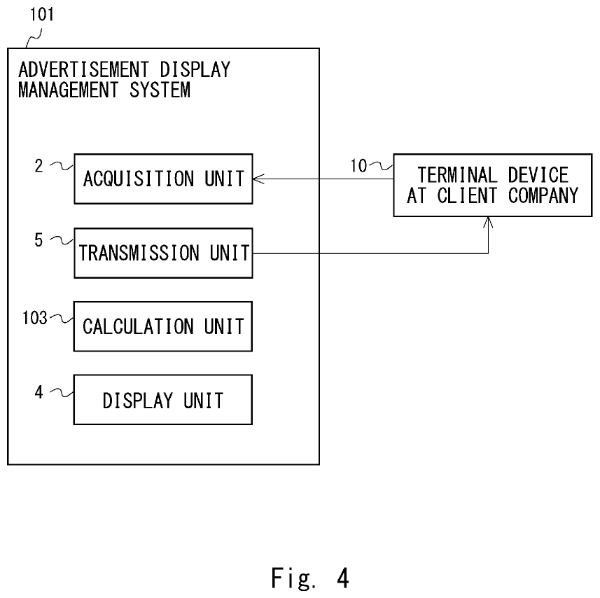

FIG. 4 is a block diagram showing a configuration of an advertisement display management system 101 according to a second embodiment. As shown in FIG. 4, the configuration of the advertisement display management system 101 according to the second embodiment differs from the configuration of the advertisement display management system 1 according to the first embodiment shown in FIG. 1 in that the advertisement display management system 101 includes a transmission unit 5 that transmits information to the terminal device 10.

A calculation unit 103 has a function of calculating, in advance, the amount of electricity that can be generated during the prescribed period at the electricity generating facility where a renewable energy source is used and which is installed at the airport and the maximum amount of electricity that can be purchased by the client company based on the information regarding the weather during the prescribed period in addition to the function of the calculation unit 3 shown in FIG. 1. Here, the information regarding the weather during the prescribed period is acquired, for example, via a network rather than from a weather forecast on a cloud system. The transmission unit 5 transmits information regarding the maximum amount of electricity that can be purchased by the client company to the terminal device 10 at the client company before the acquisition unit 2 acquires the amount of electricity to be purchased by the client from the terminal device 10 at the client company.

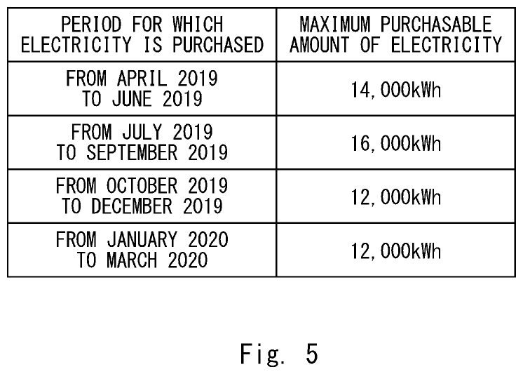

FIG. 5 is a schematic diagram showing an example of the information transmitted from the transmission unit 5 to the terminal device 10. Here, the information to be transmitted is a period for which electricity is purchased and the maximum amount of electricity that can be purchased for the period as described above. The amount of electricity that can be generated at the electricity generating facility where the renewable energy is used and which is installed at the airport is affected by the weather. For example, when the electricity generating facility installed at the airport is a solar-powered system, the maximum amount of electricity that can be purchased varies depending on the hours of sunlight during the period for which the electricity is purchased. Thus, as shown in FIG. 5, there is a possibility that the amount of electricity (16,000 kWh) that was supplied to the client company during the summer season (July 2019 to September 2019) cannot be supplied during the winter season (January 2020 to March 2020) to the client company.

As described above, the transmission unit 5 of the advertisement display management system 101 according to the second embodiment transmits information like that shown in FIG. 5 to the client company before the acquisition unit 2 acquires the amount of electricity to be purchased from the terminal device 10 at the client company. By this structure, the client company can grasp, in advance, the amount of electricity that can be purchased from the electricity generating facility where the renewable energy is used and which is installed at the airport, and hence the client company can purchase electricity generated by the renewable energy from the airport as planned.

Further, the calculation unit 103 may calculate the discount rate pertaining to the cost for displaying an advertisement at the airport in accordance with the amount of electricity to be purchased in advance and the transmission unit 5 may transmit information related to the discount rate to the terminal device 10 before the acquisition unit 2 acquires information on the amount of electricity to be purchased from the terminal device 10 at the client company.

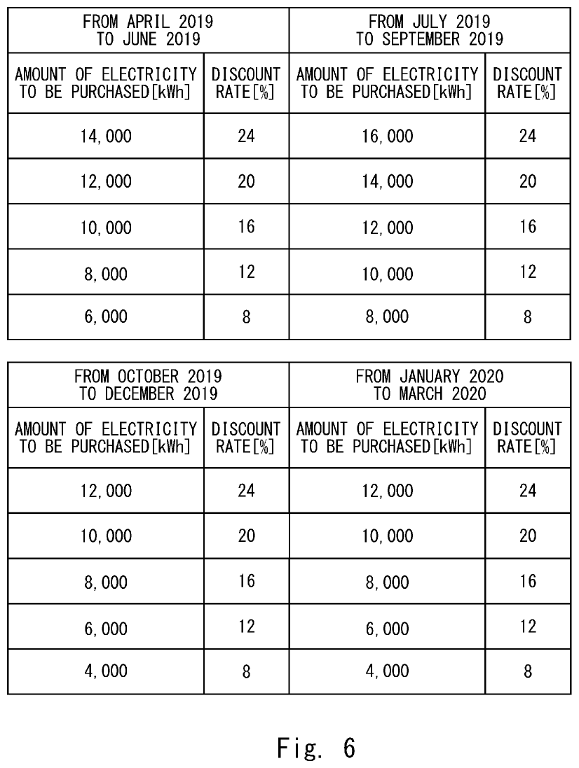

FIG. 6 is a schematic diagram showing an example of information regarding the discount rate pertaining to the cost for displaying an advertisement at the airport that is transmitted from the transmission unit 5 to the terminal device 10. As shown in FIG. 6, the discount rate of the cost for displaying an advertisement at the airport is set so that it becomes higher as the amount of electricity to be purchased becomes larger. Note that the upper limit of the amount of electricity to be purchased is set to be the maximum amount of electricity that can be purchased by the client company described above. For example, for the period from April 2019 to June 2019, the discount rate is set to be 24% when the amount of electricity to be purchased is 14,000 kWh and the discount rate is set to be 8% when the amount of electricity to be purchased is 6,000 kWh.

By this structure, it is possible to promote purchase of electricity generated by the renewable energy from the electricity generating facility of the airport by the client company who has their advertisement displayed at the airport.

Note that the present disclosure is not limited to the aforementioned-embodiments and can be modified as appropriate without departing from the gist of the present disclosure.

For example, in the above-described embodiments, the advertisement display management system according to the present disclosure has been described as a hardware configuration, but the present disclose is not limited thereto. In the present disclosure, any processing of the advertisement display management system can be achieved by a processor, such as a CPU (Central Processing Unit), loading and executing a computer program stored in a memory.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An advertisement display management system comprising:
an acquisition unit configured to acquire, from a terminal device at a client company, an amount of electricity to be purchased for a prescribed period from an electricity generating facility where a renewable energy source is used and which is installed at an airport and data of an advertisement that is to be displayed at the airport during the prescribed period;
a calculation unit configured to calculate an emission reduction amount of CO₂ equivalent to the amount of electricity to be purchased; and
a display unit installed at the airport and configured to display the data of the advertisement, the amount of electricity to be purchased, and the emission reduction amount of CO₂.

2. The advertisement display management system according to claim 1 further comprising a transmission unit configured to transmit information to the terminal device, wherein:
the calculation unit is configured to calculate an amount of electricity that can be generated at the electricity generating facility during the prescribed period and the maximum amount of electricity that can be purchased by the client company based on information regarding the weather during the prescribed period; and
the transmission unit is configured to transmit information regarding the maximum amount of electricity that can be purchased by the client company to the terminal device before the acquisition unit acquires the amount of electricity to be purchased.

3. The advertisement display management system according to claim 2, wherein
the calculation unit is configured to calculate, in advance, a discount rate pertaining to a cost for displaying an advertisement at the airport in accordance with the amount of electricity to be purchased; and
the transmission unit is configured to transmit information regarding the discount rate to the terminal device before the acquisition unit acquires the amount of electricity to be purchased.
